(19) United States
(12) Patent Application Publication
(10) Pub. No.: US 2007/0015300 A1
(43) Pub. Date: Jan. 18, 2007

(54) Method for fabricating a light-emitting device

(76) Inventors: Yu-Chuan Liu, Nantou (TW); Chia-Ming Lee, Nantou (TW); I-Ling Chen, Nantou (TW); Jen-Inn Chyi, Nantou (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/181,756

(22) Filed: Jul. 15, 2005

(51) Int. Cl. H01L 21/00

(52) U.S. Cl. 438/26; 438/46; 438/615

(57) ABSTRACT

The present invention discloses a method for fabricating a light-emitting device, wherein a thermosonic bonding process is utilized to join the contacts on a substrate with bond pads on the light-emitting element. Thereby, the deterioration of the substrate can be reduced, and the yield can also be promoted. Further, in the present invention, it is unnecessary to redesign the element specially, and thus, the cost can be lowered.

### BACKGROUND OF THE INVENTION

1. Field of the Invention

The present invention relates to a method for fabricating a light-emitting device, particularly to one, wherein the yield of fabricating a light-emitting device can be promoted.

2. Description of the Related Art

Light-Emitting Diode (LED) is a light-emitting element made of a semiconductor material. The element has two electrode terminals, and when a voltage is applied therebetween, a very small current will flow through the element, and light will emit owing to the potentials difference of electrons resulting from the recombination of electrons and electron holes.

Contrary to a general incandescent lamp, LED is electroluminescent and has the advantages of low energy consumption, long service life, no lamp-warming time, quick response, small size, vibration resistance, and easy mass-production. Further, LEDs can be fabricated into arrayed elements or very small ones. Therefore, LED has been universally applied in the indicator or the display device of the information, communication, or consumer electronic product, and plays an indispensable role in daily living.

According to the wavelength of the light emitted by LED, LED can be classified into Visible-Ray LED with the wavelength ranging from 450 to 680 nm and Invisible-Ray LED with the wavelength ranging from 850 to 1550 nm. According to material forming the epitaxial layer of LED, LED can be classified into Binary Compound LED, including Gallium Arsenide (GaAs), Gallium Antimonide (GaSb), Gallium Nitride (GaN), etc., Ternary Compound LED, including ternary solid solution, such as AlₓGa₁₋ₓAs, AlₓGa₁₋ₓP, In₁₋ₓGaₓAs, etc., Quaternary Compound LED, including Aluminum Indium Gallium Phosphide (AlInGaP), Aluminum Indium Gallium Arsenide (InAlGaAs), AlₓGa₁₋ₓAs_{y}P_{1-y}, etc., and GaN LED.

According to the brightness presented by LED, LED can be classified into High-Brightness LED and General-Brightness LED. As the brightness and the light-emitting efficiency of LED has a direct relationship with the material of the epitaxial layer, the material of the epitaxial layer can be used as the standard to distinguish between High-Brightness LED and General-Brightness LED. High-Brightness LED is made of a quaternary compound or a GaN-based compound, and General-Brightness LED is made of a binary or a ternary compound except GaN-based compounds.

As LED is used more and more in daily living, the manufacturer is persisting in promoting the light-emitting efficacy of LED. One measure thereof is to improve LED structure, and another is to improve LED-package technology, inclusive of improving the fluorescent power of LED and the coating technology thereof. The approaches to improve LED structure are focused on how to reduce the energy loss in LED's emitting light, and the Flip Chip Package technology, which can promote the brightness of Flip Chip Package LED to be 1.5˜2 times that of non-Flip Chip Package LED, is an effective one among those approaches.

In most fabrication processes of Flip Chip Package LED, the method of coupling the electrodes is to reflow those with a Sn-containing metallic layer at the temperature of 200˜300° C. However, this method has its disadvantages. It is only at a high temperature that the Sn-containing metallic material can be melted to enable the element to join to the substrate. Nevertheless, the element will be deteriorated at high temperature, which will lower the yield. Further, Tin is apt to compound with the metal of the wire-bonding pad, which can influence the performance of the element; therefore, a barrier layer is designed to prevent the element from the interfusion of Tin lest the ohmic contact metal be deteriorated; thus, the fabrication cost is raised.

In re those discussed above, the present invention proposes a method for fabricating a light-emitting device in order to overcome the aforementioned problems.

### SUMMARY OF THE INVENTION

The primary objective of the present invention is to provide a method for fabricating a light-emitting device, wherein a thermosonic bonding technology is utilized to join the bond pad with the contact in a eutectic means at not too high a temperature lest the plastic mold be melted owing to high temperature, and the yield is therefore promoted.

Another objective of the present invention is to provide a method for fabricating a light-emitting device, which adopts Tin-free bond pads and contacts lest the element be deteriorated owing to the interfusion of Tin, wherein the contact is formed via cutting off the tail of the wire after a wire bonding process without redesigning the element specially, and the fabrication cost is thus lowered.

To achieve the aforementioned objectives, the method for fabricating a light-emitting device of the present invention comprises the following steps: providing a substrate; forming multiple contacts on the substrate; providing a light-emitting element having multiple bond pads on its surface; and utilizing a thermosonic bonding technology to join the bond pads with the contacts in a eutectic means.

To enable the objectives, technical contents, characteristics and accomplishments of the present invention to be more easily understood, the preferred embodiments of the present invention are to be described below in cooperation with the attached drawings.

### BRIEF DESCRIPTION OF THE DRAWINGS

FIG. 1(a) to FIG. 1(e) are the perspective views showing the steps of the method for fabricating a light-emitting device according to the present invention.

### DETAILED DESCRIPTION O THE INVENTION

Owing to the important role LED plays in daily living, and owing to that the brightness of Flip Chip Package LED is 1.5˜2 times that of non-Flip Chip Package LED, the present invention proposes a method for fabricating a light-emitting device, via which Flip Chip Package LED can be fabricated.

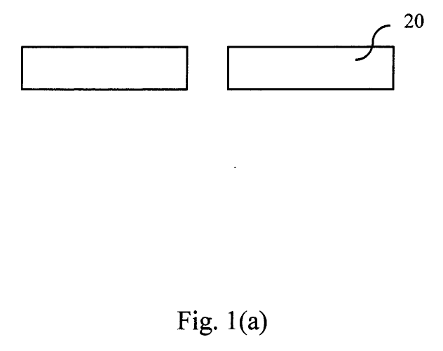

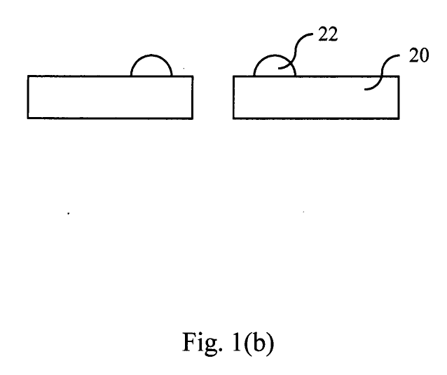

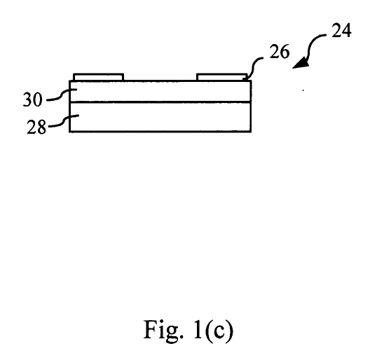

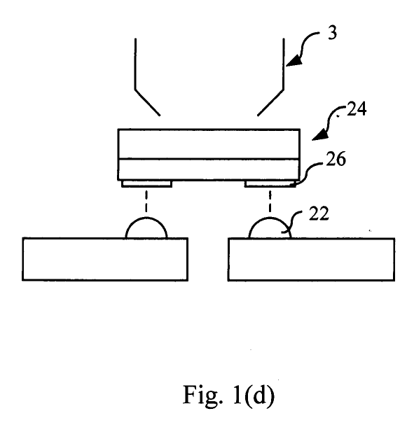

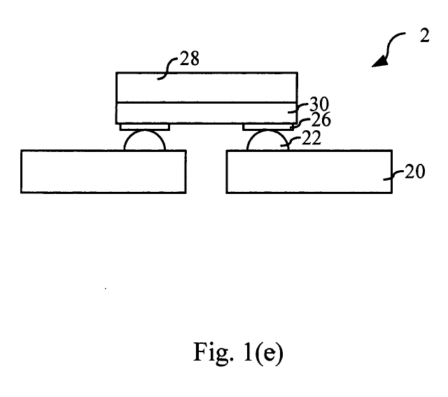

Refer to from FIG. 1(a) to FIG. 1(e) the perspective views of the steps of the method for fabricating a light-emitting device according to the present invention. Firstly, as shown in FIG. 1(a), a substrate 20 is provided; the substrate 20 can be made of a metallic material, or a plastics or can be a Printed Circuit Board (PCB), such as a Flexible Printed Circuit (FPC); the substrate 20 can also be a lead frame. As shown in FIG. 1(b), multiple contacts 22 are formed on the substrate 20, wherein ball-like contacts 22 are formed via cutting off the tails of the wires after a wire bonding process. As shown in FIG. 1(c), a light-emitting element 24 having multiple bond pads 26 on it surface is provided. As shown in FIG. 1(d), a sucking nozzle 3 is used to flip the light-emitting element 24 upside down, and a thermosonic bonding technology is utilized to join the bond pads 26 with the contacts 22 in a eutectic means, and with a compression process, the substrate 20 is further joined more tightly to the light-emitting element 24; thereby, a light-emitting device 2 is formed, and as shown in FIG. 1(e), the light-emitting device 2 is of Flip Chip Package type.

When the substrate 20 is a lead frame, there is an advantage: after a module is done, what is needed is just to join the bond pads 24 on the light-emitting element 24 with the emerging contacts 22 on the module, so that the contact-disconnection between the substrate 20 and the light-emitting element 24 can be avoided; thus, the yield can be promoted.

As shown in FIG. 1(c), the light-emitting element 24 comprises a substrate 28, an electrically-conductive layer 30 on the substrate 28, and bond pads 26 on the electrically-conductive layer 30. The substrate 28 can be made of an Alumina (Al₂O₃), and the electrically-conductive layer 30 can be formed of Gallium Nitride (GaN).

The material of the contact 22 or the bond pad 26 can be at least one of Gold (Au), Copper (Cu), Silver (Ag), Aluminum (Al), Indium (In), Tin (Sn), Platinum (Pt), Palladium (Pd), Titanium (Ti), Nickel (Ni), and Lead (Pb). A thermosonic bonding technology is utilized to join the substrate 20 to the light-emitting element 24; the available temperature for the thermosonic bonding process ranges from 80 to 300° C., and the preferred temperature for the thermosonic bonding process ranges from 80 to 180° C. The thermosonic bonding process is a combination technology of an ultrasonic bonding and a thermocompression. As the temperature of the thermosonic bonding process is relatively lower, the growth of intermetallic compound is inhibited, and thus, the deterioration of the substrate 20 resulting from high temperature is reduced.

In summary, the present invention proposes a method for fabricating a light-emitting device, wherein a wire bonding process is firstly performed; the wire tails are cut off to form multiple contacts on the substrate after wire bonding; a thermosonic bonding process and a compression process are utilized to join the contacts with the bond pads in a eutectic means so that the substrate is tightly joined to the light-emitting element. As the thermosonic bonding process is performed at not too high a temperature, the plastic mold can be free of melting resulting from high temperature, and the element can also be free of the deterioration resulting from the interfusion of Tin; thus, the yield is promoted. Further, it is unnecessary to redesign the element specially; therefore, the fabrication cost is lowered.

Those embodiments described above is to clarify the present invention to enable persons skilled in the art to understand, make and use the present invention, but not to limit the scope of the present invention. Any equivalent modification and variation according to the spirit of the present invention disclosed herein is to be included within the scope of the claims stated below.

What is claimed is:

1. A method for fabricating a light-emitting device, comprising the following steps:
providing a substrate;
forming a plurality of contacts on said substrate;
providing a light-emitting element, having a plurality of bond pads on the surface thereof; and
utilizing a thermosonic bonding process to join said bond pads with said contacts in a eutectic means.

2. The method for fabricating a light-emitting device according to claim 1, wherein said substrate is made of a metallic material, a plastic material, or a printed circuit board.

3. The method for fabricating a light-emitting device according to claim 2, wherein said circuit board is a flexible printed circuit.

4. The method for fabricating a light-emitting device according to claim 1, wherein said substrate is a lead frame having a plurality of electrically-conductive pins, and said contacts are formed on said electrically-conductive pins.

5. The method for fabricating a light-emitting device according to claim 1, wherein a plurality of leads are formed on said substrate, and said contacts are formed via cutting off said plurality of leads.

6. The method for fabricating a light-emitting device according to claim 1, wherein said light-emitting element further comprises a substrate and a electrically-conductive layer, and said bond pads are formed on said electrically-conductive layer.

7. The method for fabricating a light-emitting device according to claim 6, wherein said substrate is made of an alumina (Al₂O₃).

8. The method for fabricating a light-emitting device according to claim 6, wherein said electrically-conductive layer is formed of a gallium nitride (GaN).

9. The method for fabricating a light-emitting device according to claim 1, wherein said light-emitting element is flipped upside down, before the step of said “utilizing a thermosonic bonding process to join said bond pads with said contacts in a eutectic means”.

10. The method for fabricating a light-emitting device according to claim 1, wherein, after said “join said bond pads with said contacts”, a compression operation is further comprised to enable said substrate to be tightly joined to said light-emitting element.

11. The method for fabricating a light-emitting device according to claim 1, wherein the temperature at which said “join said bond pads with said contacts” is performed ranges from 80 to 300° C.

12. The method for fabricating a light-emitting device according to claim 11, wherein preferred said temperature at which said “join said bond pads with said contacts” is performed ranges from 80 to 180° C.

13. The method for fabricating a light-emitting device according to claim 1, wherein the material of said contacts or said bond pads can be at least one of Gold (Au), Copper (Cu), Silver (Ag), Aluminum (Al), Indium (In), Tin (Sn), Platinum (Pt), Palladium (Pd), Titanium (Ti), Nickel (Ni), and Lead (Pb).
